(19) United States
(12) Patent Application Publication
(10) Pub. No.: US 2025/0379097 A1
(43) Pub. Date: Dec. 11, 2025

(54) STAGE, INSPECTION DEVICE, AND METHOD OF OPERATING STAGE

(71) Applicant: Tokyo Electron Limited, Tokyo (JP)

(72) Inventors: Yuki HIROSE, Nirasaki City (JP); Masahito KOBAYASHI, Nirasaki City (JP)

(21) Appl. No.: 19/296,229

(22) Filed: Aug. 11, 2025

Related U.S. Application Data
(63) Continuation of application No. PCT/JP2024/003687, filed on Feb. 5, 2024.

(30) Foreign Application Priority Data
Feb. 17, 2023 (JP) 2023-023776

(51) Int. Cl. H01L 21/687; H01L 21/67

(52) U.S. Cl. CPC H01L 21/68742; H01L 21/67259; H01L 21/68764; H01L 21/68785

(57) ABSTRACT

A stage includes a substrate support configured to support a substrate, one or more lifters configured to raise and lower the substrate support, and a controller configured to control operations of the one or more lifters. Each of the one or more lifters includes a drive motor configured to output a thrust force to raise and lower the substrate support based on rotation, and an electromagnetic brake configured to apply a brake holding force to the one or more lifters to maintain a height position of the substrate support. The controller controls the height position of the substrate support while mutually linking the thrust force of the drive motor and the brake holding force of the electromagnetic brake.

### CROSS-REFERENCE TO RELATED APPLICATIONS

This application is a bypass continuation application of International Application No. PCT/JP2024/003687 having an international filing date of Feb. 5, 2024 and designating the United States, the international application being based upon and claiming the benefit of priority from Japanese Patent Application No. 2023-023776, filed on Feb. 17, 2023, the entire contents of which are incorporated herein by reference.

### TECHNICAL FIELD

The present disclosure relates to a stage, an inspection device, and a method of operating the stage.

### BACKGROUND

Patent Document 1 discloses an inspection device (probe device) which includes a stage (main chuck) for placing a wafer thereon and that performs electrical inspection on the wafer by moving the stage in three dimensional directions.

In this type of inspection device, during an overdrive in which the wafer is raised for the electrical inspection, the stage may tilt due to a load applied from multiple probes of a probe card. For this reason, the inspection device calculates a correction amount of movement of the stage in the three dimensional directions during the overdrive based on information about the stage, information about the wafer, and information about the probe card, and performs a process of moving the stage according to the calculated correction amount of movement.

### PRIOR ART DOCUMENT

### Patent Document

Patent Document 1: Japanese Laid-Open Patent Publication No. H11-030651

### SUMMARY

According to one embodiment of the present disclosure, a stage includes a substrate support configured to support a substrate; one or more lifters configured to raise and lower the substrate support; and a controller configured to control operations of the one or more lifters, wherein each of the one or more lifters includes a drive motor configured to output a thrust force to raise and lower the substrate support based on rotation, and an electromagnetic brake configured to apply a brake holding force to the one or more lifters to maintain a height position of the substrate support, and the controller controls the height position of the substrate support while mutually linking the thrust force of the drive motor and the brake holding force of the electromagnetic brake.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an inspection device including a stage according to one embodiment.

FIG. 2 is a schematic side view showing a stage installed in an inspector.

FIG. 3 is an enlarged perspective view showing a Z-axis moving mechanism of the stage.

FIG. 4 is a longitudinal cross-sectional view showing the Z-axis moving mechanism of the stage.

FIG. 5 is a block diagram showing a configuration for controlling operations of a drive motor and an electromagnetic brake of the Z-axis moving mechanism.

FIG. 6A is a graph showing a relationship between a brake power of the electromagnetic brake and a brake torque of the electromagnetic brake.

FIG. 6B is a graph showing a relationship between the brake power of the electromagnetic brake and a target position of a base and the brake torque.

FIG. 6C is a graph showing a voltage-current characteristic of the electromagnetic brake.

FIG. 7A is a timing chart showing a method of operating the stage according to this embodiment.

FIG. 7B is a timing chart showing a method of operating a stage according to a comparative example.

FIG. 8A is a timing chart showing a relationship between a motor torque and a brake torque when a PWM-control is performed.

FIG. 8B is a timing chart showing an example in which the PWM-control is performed in a stage equipped with n electromagnetic brakes.

### DETAILED DESCRIPTION

Hereinafter, an embodiment of the present disclosure will be described with reference to the drawings. In the drawings, the same components will be denoted by like reference numerals, and duplicate descriptions thereof may be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

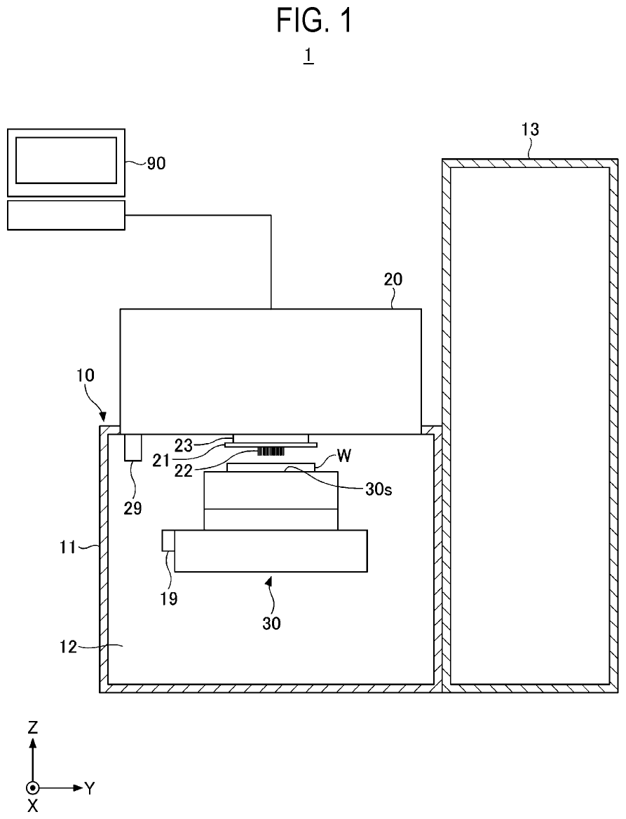

FIG. 1 is a schematic cross-sectional view showing an inspection device 1 including a stage 30 according to one embodiment. As shown in FIG. 1, the inspection device 1 according to one embodiment inspects electrical characteristics of a wafer W, which is an example of a substrate. A semiconductor device, which is a device under test (DUT), is formed on the surface of the wafer W. The substrate is not limited to the wafer W, but may be a carrier, a glass substrate, a single chip, an electronic circuit board, or the like on which the device under test is arranged. The device under test is also not limited to the semiconductor device, and may be other electronic devices, or the like.

The inspection device 1 includes an inspector 10 configured to actually perform inspection, a loader 13 installed adjacent to the inspector 10, and a tester 20 installed above the inspector 10. Further, the inspection device 1 includes a controller 90 that controls the operations of the inspector 10, the loader 13, and the tester 20.

The inspector 10 includes a rectangular parallelepiped housing 11 and an inspection chamber 12 defined inside the housing 11. The inspection chamber 12 accommodates a stage 30 that transfers the wafer W placed thereon to a desired position in a three-dimensional coordinate.

A front opining unified pod (FOUP) (not shown) in which a plurality of wafers W are waiting is set on the loader 13. The loader 13 includes a transfer device (not shown), which takes out the wafer W from the FOUP and delivers the wafer W to the stage 30 in the inspection chamber 12. Further, the loader 13 takes out the inspected wafer W from the stage 30 by the transfer device and stores the same in the FOUP.

The inspector 10 includes a probe card 21 connected to the tester 20 via an interface 23 above the inspection chamber 12. The probe card 21 includes a plurality of probes 22 at positions facing the wafer W. When the wafer W is moved by the stage 30, each probe 22 comes into contact with an electrode pad, a solder bump, or the like of each device under test on the wafer W. Thus, the tester 20 outputs power and various signals to the device under test via the probe card 21 and the interface 23, and also receives signals transmitted from the device under test via the probe card 21 and the interface 23.

The tester 20 includes a motherboard (not shown) which is connected to the interface 23. The motherboard has a number of slots to which a number of test boards (not shown) may be attached, and is connected to the controller 90. The motherboard determines a quality of each device under test on the wafer W based on signals transmitted from the device under test. The tester 20 may perform multiple types of tests by appropriately replacing the test boards.

Further, the inspection device 1 may include an inspection-side camera 29 provided at an appropriate position in the inspection chamber 12 to capture an image of the wafer W on the stage 30. The inspection-side camera 29 captures, for example, an inclination of the stage 30 and a position of the wafer W placed on the stage 30. Alternatively, the inspection device 1 may include a stage-side camera 19 that captures an image of a contact state between the probe card 21 or each probe 22 and the wafer W, and the like.

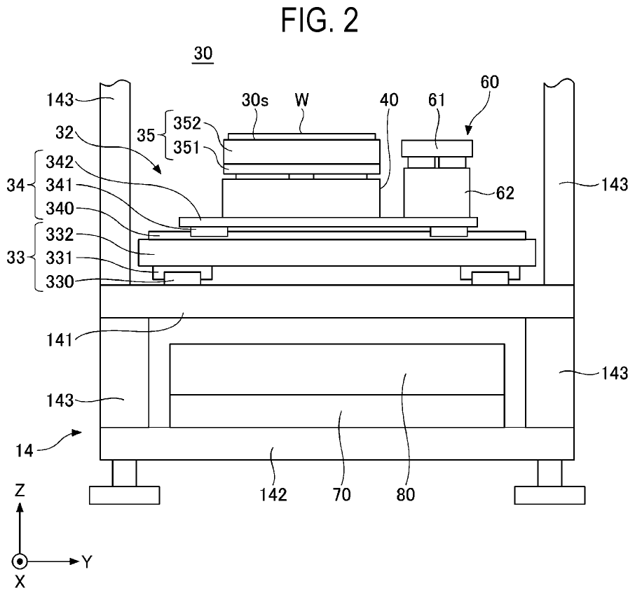

FIG. 2 is a schematic side view showing the stage 30 installed in the inspector 10. As shown in FIG. 2, the stage 30 is installed on a frame structure 14 that supports a panel (not shown) constituting an appearance of the housing 11. A flat placement surface 30s that supports the wafer W is formed on an upper surface of the stage 30.

The stage 30 transfers the wafer W placed on the placement surface 30s to an appropriate three-dimensional position (in an X-axis direction, a Y-axis direction, and a Z-axis direction) in the inspection chamber 12. For example, the stage 30 moves in a horizontal direction (the X-axis and Y-axis directions) between a position near (or inside) the loader 13 in FIG. 1 and a position facing the probe card 21 to adjust a horizontal position of the wafer W. In addition, the stage 30 moves up and down in a vertical direction (the Z-axis direction) at the position facing the probe card 21 and the wafer W to adjust a vertical position of the wafer W.

The stage 30 includes a moving part 32 (an X-axis moving mechanism 33, a Y-axis moving mechanism 34, and a Z-axis moving mechanism 40), a base 35, a needle grinding mechanism 60, a stage controller 70, and a driver part 80. On the other hand, the frame structure 14 is a two-stage structure including an upper base 141 that supports the moving part 32, a lower base 142 that supports the stage controller 70 and the driver part 80, and a plurality of support columns 143 provided at four corners of the upper base 141 and the lower base 142.

The X-axis moving mechanism 33 of the moving part 32 includes a plurality of guide rails 330 fixed to an upper surface of the upper base 141 and extending along the X-axis direction, a plurality of X-axis movable bodies 331 arranged between the guide rails 330, and an X-axis table 332 supported by each of the X-axis movable bodies 331. The X-axis table 332 includes an X-axis driving part (motor, gear mechanism, and the like) (not shown) that is connected to the driver part 80. The X-axis driving part reciprocates each of the X-axis movable bodies 331 and the X-axis table 332 in the X-axis direction based on power supplied from the driver part 80, thereby adjusting an X-axis coordinate of the wafer W.

The Y-axis moving mechanism 34 includes a plurality of guide rails 340 fixed to an upper surface of the X-axis table 332 and extending along the Y-axis direction, a plurality of Y-axis movable bodies 341 arranged between the guide rails 340, and a Y-axis table 342 supported by each of the Y-axis movable bodies 341. The Y-axis table 342 includes a Y-axis driving part (motor, gear mechanism, and the like) (not shown) that is connected to the driver part 80. The Y-axis driving part reciprocates each of the Y-axis movable bodies 341 and the Y-axis table 342 in the axial direction based on power supplied from the driver part 80, thereby adjusting a Y-axis coordinate of the wafer W.

The Z-axis moving mechanism 40 is installed on the Y-axis table 342 and holds the base 35 at its upper portion. The Z-axis moving mechanism 40 constitutes a lifting mechanism of this embodiment that raises and lowers the wafer W placed on the placement surface 30s of the base 35 by displacing the base 35 in the Z-axis direction (the vertical direction). A configuration of the Z-axis moving mechanism 40 will be described in detail later.

The base 35 transferred by the moving part 32 includes a bottom plate 351 supported by the Z-axis moving mechanism 40, and a chuck top 352 having a placement surface 30s stacked on the bottom plate 351. The bottom plate 351 is supported by the four lifters 45 of the Z-axis moving mechanism 40, which will be described later. The chuck top 352 has a circular shape with a larger diameter than the wafer W in a plan view, and is formed to be thicker than the bottom plate 351. Although not shown, the chuck top 352 may include an appropriate holding means (vacuum suction, mechanical chuck, or the like) for holding the wafer W, a temperature control mechanism for adjusting a temperature of the placement surface 30s, a temperature sensor for detecting the temperature of the placement surface 30s, and the like.

The needle grinding mechanism 60 of the stage 30 is installed at a position adjacent to the Z-axis moving mechanism 40 on the Y-axis table 342. A grinding body 61 for grinding the probes 22 protruding downward from the probe card 21 is provided in an upper portion of the needle grinding mechanism 60. The needle grinding mechanism 60 has a grinding-side Z-axis moving mechanism 62 for displacing the grinding body 61 in the Z-axis direction. The grinding-side Z-axis moving mechanism 62 has a configuration substantially similar to that of the Z-axis moving mechanism 40.

The stage controller 70 is connected to the controller 90 of the inspection device 1 to control an operation of the stage 30 based on a command from the controller 90. The stage controller 70 includes, for example, a main controller that controls the entire operation of the stage 30, a PLC that controls an operation of the moving part 32, a temperature controller that controls the temperature adjustment mechanism, an illumination controller, a power supply unit, or the like (all of which are not shown). The main controller of the stage controller 70 may be a computer-embedded board including one or more processors, a memory, an input/output interface, and electronic circuits (not shown). The one or more processors are a combination of one or more of a central processing unit (CPU), a graphics processing unit (GPU), an application specific integrated circuit (ASIC), an field programmable gate array (FPGA), a circuit made of a plurality of discrete semiconductors, and the like, and are configured to execute and process a program stored in the memory. The memory includes a non-volatile memory and a volatile memory.

The stage controller 70 controls the driver part 80 based on the command from the controller 90 to receive the wafer W from the loader 13 onto the base 35, and then operates the moving part 32 to move the wafer W in the horizontal direction. Then, when the wafer W is at the position facing the probe card 21, the stage controller 70 causes the Z-axis moving mechanism 40 of the moving part 32 to raise the base 35, and brings the wafer W into contact with the probes 22 of the probe card 21. In this state, the controller 90 begins the electrical inspection by the tester 20. After the tester 20 finishes the inspection, the stage controller 70 performs a reverse operation to lower and horizontally move the inspected wafer W, and returns the same to the loader 13.

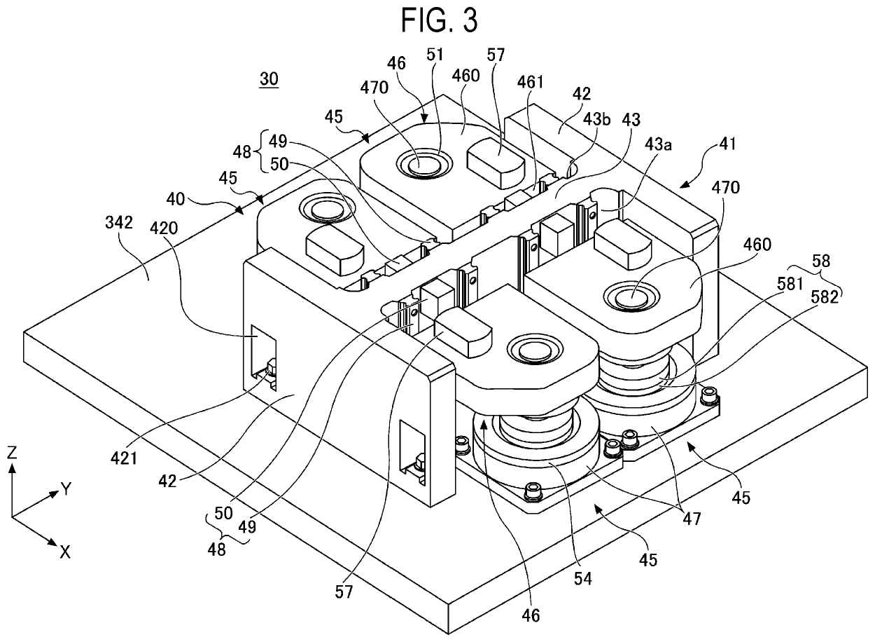

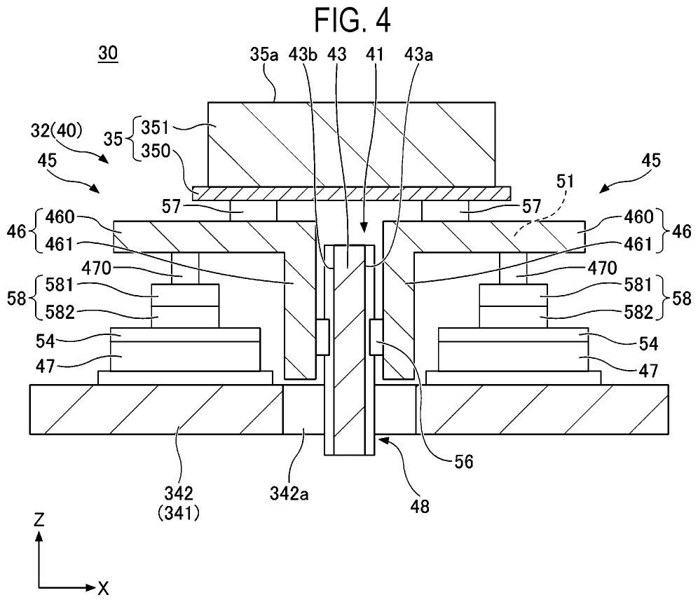

FIG. 3 is an enlarged perspective view of the Z-axis moving mechanism 40 of the stage 30. FIG. 4 is a longitudinal cross-sectional view of the Z-axis moving mechanism 40 of the stage 30. As shown in FIGS. 3 and 4, the Z-axis moving mechanism 40 includes a support frame 41 installed on the Y-axis table 342. The support frame 41 is a member that continuously extends in a direction perpendicular to a lifting direction of the base 35 (the horizontal direction: the X-axis and Y-axis directions). The support frame 41 protects the four lifters 45 of the Z-axis moving mechanism 40 and guides the raising and lowering operation of each of the lifters 45. In other words, the Z-axis moving mechanism 40 is configured to raise and lower the above-mentioned one base 35 (see FIG. 2) by the four lifters 45.

The support frame 41 includes a pair of sidewalls 42 and one connecting wall 43 extending between the pair of sidewalls 42, and is formed in an H-shape in a plan view. Upper surfaces of the pair of sidewalls 42 and an upper surface of the connecting wall 43 are flush with each other. Thus, an upper portion of the support frame 41 is formed in a flat shape.

The pair of sidewalls 42 are fixed to the upper surface of the Y-axis table 342. In a side view, each of the sidewalls 42 has a substantially rectangular shape that extends long in the X-axis direction and short in the Z-axis direction. The connecting wall 43 is connected to a middle position of each of the sidewalls 42 in the X-axis direction (long side). A plurality of screw fastening spaces 420 is formed at predetermined positions near lower surfaces of the pair of sidewalls 42. Fixing screws 421 that pass through the respective sidewalls 42 from the screw fastening spaces 420 are threadedly fastened to the Y-axis table 342, thereby firmly fixing the support frame 41 to the Y-axis table 342.

The connecting wall 43 is formed in a substantially rectangular shape extending in the Y-axis direction (width direction) and the Z-axis direction (height direction or vertical direction). As shown in FIG. 4, a length of the connecting wall 43 in the Y-axis direction is longer than that of the sidewall 42 in the X-axis direction. With the support frame 41 fixed to the Y-axis table 342, the lower portion of the connecting wall 43 is inserted into a hole 342a formed in the Y-axis table 342 and protrudes downward beyond the Y-axis movable body 341.

As shown in FIG. 3, the four lifters 45 are arranged in two regions separated by the connecting wall 43. Each of the lifters 45 includes a Z-axis movable body 46 that directly supports the base 35, a drive motor 47 that raises and lowers the Z-axis movable body 46, and a guide part 48 that guides the Z-axis movable body 46 as it moves up and down.

The Z-axis moving mechanism 40 includes two guide parts 48 on one wall surface 43a of the connecting wall 43 in the X-axis direction, and two guide parts 48 on the other wall surface 43b of the connecting wall 43 in the X-axis direction. Each of the guide parts 48 includes a pair of rails 49 extending in the Z-axis direction. The pair of rails 49 extend linearly from the upper end to the lower end of the connecting wall 43. In addition, each of the guide parts 48 includes a movement limiting block 50 installed on an upper portion of each of the wall surfaces 43a and 43b of the connecting wall 43 to limit an upward movement of the Z-axis movable body 46.

The drive motor 47 of the lifter 45 is fixed to the Y-axis table 342 and has a shaft portion 470 protruding in a positive Z-axis direction. The type of the drive motor 47 is not particularly limited, but a servo motor capable of controlling a rotational position and rotational speed of the shaft portion 470 may be used. In particular, in order to reduce a size of the Z-axis moving mechanism 40, it is preferable to use a direct drive motor as the drive motor 47. The direct drive motor is arranged at a low position along an axial direction without a reducer, and may rotate at a low speed and high torque. Alternatively, a magnetic geared motor may be used as the drive motor 47.

A reducer may be provided between the drive motor 47 and the Z-axis movable body 46 to reduce a rotational speed of the drive motor 47. The lifter 45 may include a magnetic reduction mechanism that reduces the rotational speed of the drive motor 47, either in the drive motor 47 itself or between the drive motor 47 and the Z-axis movable body 46.

The drive motor 47 includes an encoder 54 that detects a rotation angle of the shaft portion 470 or a rotor (not shown). The drive motor 47 may also include a torque sensor (not shown) that detects a load value applied to the rotor from the base 35 as torque (current value).

A power convertor 51 is provided between the shaft portion 470 extending in the Z-axis direction and the Z-axis movable body 46. For example, the power convertor 51 may be a ball screw mechanism having a helical thread on an outer circumferential surface of the shaft portion 470 and a nut threadedly coupled into a hole through which the shaft portion 470 of the Z-axis movable body 46 is inserted. With the power convertor 51, the lifter 45 may raise and lower the Z-axis movable body 46 under the rotation of the shaft portion 470. A configuration of the power convertor 51 is not particularly limited, and various mechanisms capable of converting the rotational motion of the drive motor 47 into a linear motion may be adopted.

On the other hand, the Z-axis movable bodies 46 of the lifter 45 are members that support the base 35, and are raised and lowered based on the drive of the drive motor 47, thereby raising and lowering the base 35. The Z-axis moving mechanism 40 according to this embodiment is capable of adjusting a tilt of the base 35 by individually raising and lowering each of the four Z-axis movable bodies 46 (of the lifter 45).

The Z-axis movable body 46 is provided on its upper surface with a contact member 57 which comes into contact with the bottom plate 351 of the base 35. In other words, the base 35 is supported by four contact members 57. The contact members 57 are formed as a hard block having a flat upper surface.

As shown in FIG. 4, the Z-axis movable body 46 includes a horizontal extension body 460 parallel to the horizontal direction (the X-axis and Y-axis directions) and a vertical extension body 461 connected to the horizontal extension body 460 and parallel to the vertical direction. The Z-axis movable body 46 is formed in a substantially L-shape in a longitudinal cross-sectional view. The nut of the power convertor 51 is provided on the horizontal extension body 460. The vertical extension body 461 faces the connecting wall 43 at a position adjacent to the connecting wall 43 of the support frame 41, and includes a pair of sliders 56 formed on the opposing surface and arranged on the pair of rails 49. The sliders 56 are engaged with the rails 49 to guide the movement in the Z-axis direction (the extension direction of the rails 49). The rails 49 and the sliders 56 guide the movement of the Z-axis movable body 46 in the Z-axis direction while preventing the Z-axis movable body 46 from coming off in the horizontal direction (the X-axis and Y-axis directions).

The Z-axis moving mechanism 40 according to this embodiment includes an electromagnetic brake 58 provided on the upper portion of the drive motor 47. The electromagnetic brake 58 has an annular shape that surrounds a periphery of the shaft portion 470.

For example, the electromagnetic brake 58 includes a brake stator 581 fixed to the drive motor 47 (or another member), and a brake armature 582 rotatable relative to the brake stator 581. A coil (not shown) is accommodated in the brake stator 581 to apply a magnetic force to the brake armature 582 based on the supply of the brake power to the electromagnetic brake 58. The brake armature 582 is connected to an outer circumferential surface of the shaft portion 470 by appropriate connecting means (for example, spline fitting), and is rotatable integrally with the shaft portion 470.

The electromagnetic brake 58 attracts the brake armature 582 to the brake stator 581 by supplying the brake power to the coil. This attraction of the brake armature 582 causes the brake armature 582 to come into contact with a friction portion (not shown) provided between the brake stator 581 and the brake armature 582. This enables the electromagnetic brake 58 to stop the rotation of the brake armature 582 and the shaft portion 470, or to unrotatably hold the shaft portion 470.

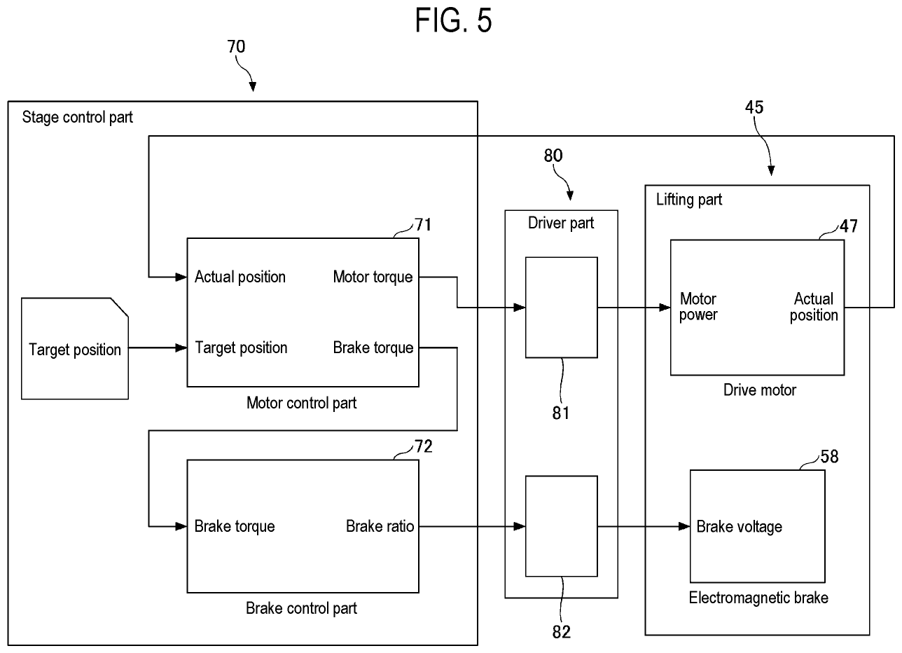

FIG. 5 is a block diagram showing a configuration for controlling the operations of the drive motor 47 and the electromagnetic brake 58 of the Z-axis moving mechanism 40. As shown in FIG. 5, the stage controller 70 includes a motor controller 71 and a brake controller 72 as functional parts for controlling each of the four lifters 45 (the drive motor 47 and the electromagnetic brake 58). The driver part 80 includes a servo amplifier 81 connected to the motor controller 71 and a voltage controller 82 connected to the brake controller 72. Locations where the motor controller 71, the brake controller 72, the servo amplifier 81, and the voltage controller 82 are installed are not particularly limited. For example, all the functional parts may be provided in the driver part 80.

The motor controller 71 receives a target position in the Z-axis direction, which corresponds to the connected drive motor 47 and Z-axis movable body 46, from the stage controller 70. The stage controller 70 calculates a target position for each drive motor 47 based on, for example, a position command relating to the lifting position of the entire base 35 and detection information relating to the load that the base 35 receives from the probe 22, and the like, and sends the same to the motor controller 71.

The motor controller 71 sets a motor torque, which is the thrust force of the drive motor 47, and a brake torque, which is the brake holding force of the electromagnetic brake 58, based on the received target position. For example, the motor controller 71 calculates a holding force (the sum of the motor torque and the brake torque, that is, the load received by the stage 30) required for holding the base 35 in the lifter 45 based on the received target position. Then, the motor controller 71 appropriately allocates the calculated holding force to the motor torque and the brake torque. In other words, the motor controller 71 stores a cooperative control algorithm for the drive motor 47 and the electromagnetic brake 58.

The motor controller 71 sends the set motor torque to the servo amplifier 81 of the driver part 80, and the servo amplifier 81 supplies motor power corresponding to the motor torque to the drive motor 47. As a result, the drive motor 47 may rotate the shaft portion 470 according to the motor torque of the motor controller 71. In addition, the drive motor 47 detects an actual position of the shaft portion 470 by the encoder 54 (see FIG. 3) when the shaft portion 470 rotates, and feeds back the actual position to the motor controller 71. As a result, the motor controller 71 may calculate a deviation between the actual position of the shaft portion 470 and the target position, and may perform control so that a gain of the motor torque with respect to the deviation and the brake torque coincide with each other. The motor controller 71 has a threshold value for comparison with the deviation between the actual position and the target position, and may perform control such as reducing the brake torque of the electromagnetic brake 58 when the deviation becomes equal to or greater than the threshold value. As a result, it is possible to suppress the positioning speed from being reduced due to the brake torque of the electromagnetic brake 58.

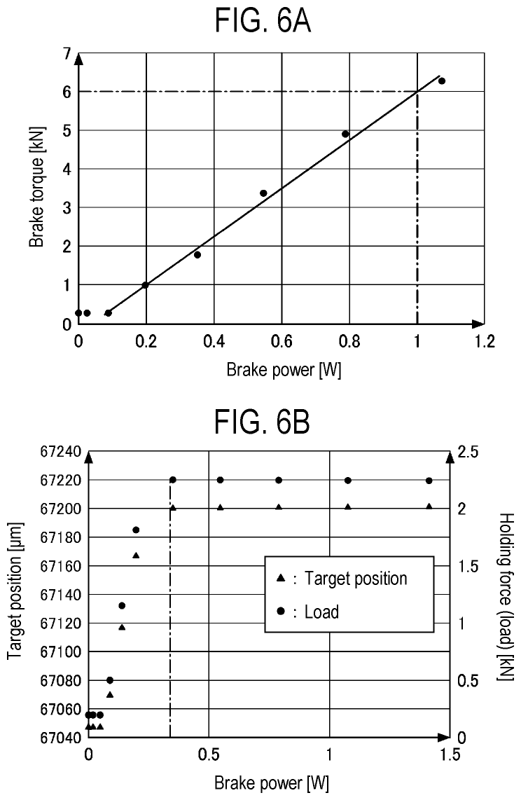

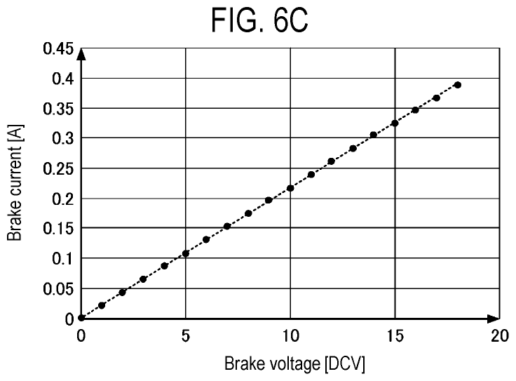

The brake controller 72 is configured to perform open loop control. The brake controller 72 receives the brake torque set in the motor controller 71 and calculates a brake ratio of the electromagnetic brake 58. The brake ratio is a ratio between the brake torque at which the electromagnetic brake 58 holds the shaft portion 470 of the drive motor 47 (that is, the height position of the Z-axis movable body 46) and the brake power (power consumption). Next, characteristics of the electromagnetic brake 58 applied to the Z-axis moving mechanism 40 will be described in detail with reference to FIGS. 6A to 6C.

FIG. 6A is a graph showing a relationship between the brake power of the electromagnetic brake 58 and the brake torque of the electromagnetic brake 58. FIG. 6B is a graph showing a relationship between the brake power of the electromagnetic brake 58 and the target position and load of the base 35. FIG. 6C is a graph showing voltage-current characteristics of the electromagnetic brake 58. The electromagnetic brake 58 normally operates in only two modes: an operating mode in which the brake is in an exciting state, and a non-operating mode in which the exciting state of the brake is released. However, as shown in FIG. 6A, the brake torque for holding the shaft portion 470 of the electromagnetic brake 58 increases linearly with an increase in the brake power after the brake stator 581 applies friction to (engages with) the brake armature 582. For example, when 0.2 W is supplied as the brake power of the electromagnetic brake 58, the brake torque of the electromagnetic brake 58 is about 1 kN, and when 1 W is supplied as the brake power of the electromagnetic brake 58, the brake torque of the electromagnetic brake 58 is about 6 kN.

In addition, during the overdrive in which the base 35 is further raised after the wafer W is brought into contact with each probe 22, the holding force (load) applied to each lifter 45 increases as the target position of the stage controller 70 rises. Therefore, as shown in FIG. 6B, the holding force (the sum of the motor torque and the brake torque) required for each lifter 45 also increases. In FIG. 6B, the black triangle indicates the position of the stage 30, and the black circle indicates the holding force (load received by the stage 30) required for each lifter 45. After the raising of the base 35 ends and the target position becomes constant, the holding force also becomes constant accordingly. For example, when the target position (holding force) becomes constant, 2.25 kN is required as the brake torque required for the electromagnetic brake 58. The brake power required for the electromagnetic brake 58 to have the brake torque of 2.25 kN is about 0.4 W to 0.5 W (see FIG. 6A). In other words, when the electromagnetic brake 58 is applied, the load applied to the base 35 may be held with a brake power of 0.5 W.

As shown in FIG. 6C, in the electromagnetic brake 58, the brake current increases linearly with an increase in the brake voltage. In other words, the electromagnetic brake 58 has a linear resistance. Therefore, when controlling the brake torque of the electromagnetic brake 58, the stage controller 70 only needs to control the brake voltage supplied to the electromagnetic brake 58.

Referring back to FIG. 5, the brake controller 72 receives the brake torque (for example, the brake torque of 2.25 kN corresponding to the target position in FIG. 6B) from the motor controller 71. The brake controller 72 holds information (function, table, and the like) indicating the relationship between the brake torque and the brake power, and calculates the brake ratio, which is the ratio of the brake power supplied by the driver part 80 to the electromagnetic brake 58, based on the received brake torque.

Further, the voltage controller 82 receives the brake ratio from the brake controller 72 and calculates a brake voltage for controlling the electromagnetic brake 58. Then, the voltage controller 82 controls the power from a power source (not shown) to supply the calculated brake voltage to the electromagnetic brake 58, thereby controlling the electromagnetic brake 58.

The driver part 80 may control the motor torque of the drive motor 47 and the brake torque of the electromagnetic brake 58 by executing, for example, PWM-control in which a pulse wave is supplied with respect to the drive motor 47 and the electromagnetic brake 58. This enables the stage 30 to control the drive motor 47 and the electromagnetic brake 58 in a more favorable coordinated manner.

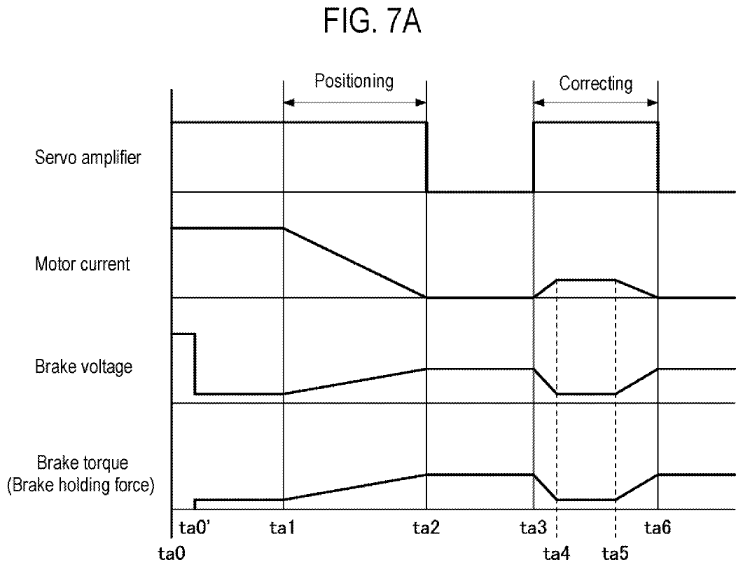

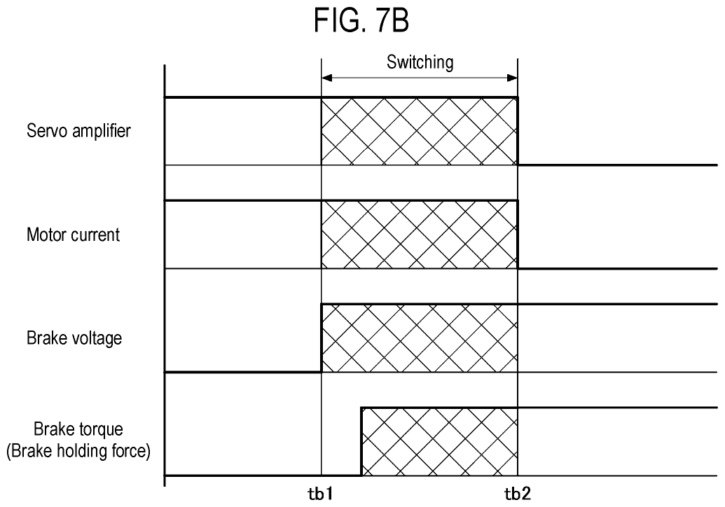

The inspection device 1 and the stage 30 according to this embodiment are basically configured as described above. A method of operating the stage 30 will be described below with reference to FIGS. 7A and 7B. FIG. 7A is a timing chart showing the method of operating the stage 30 according to this embodiment. FIG. 7B is a timing chart showing a method of operating a stage according to a comparative example.

The stage according to the comparative example shows a case where the drive motor 47 and the electromagnetic brake 58 are not subjected to the coordinated control and the Z-axis moving mechanism 40 is operated by switching the electromagnetic brake 58 between the operating mode and the non-operating mode. When the stage is raised by the Z-axis moving mechanism 40, as shown in FIG. 7B, the stage controller 70 turns on the servo amplifier 81 of the driver part 80, and outputs the motor power from the driver part 80 to the drive motor 47. The motor power (motor current) is a constant value. Thus, the drive motor 47 is operated to raise the Z-axis movable body 46.

For example, when the stage reaches the target position at time tb1, the stage controller 70 performs control to switch from driving the drive motor 47 to driving the electromagnetic brake 58. However, even if the brake power is supplied from the driver part 80, the electromagnetic brake 58 cannot immediately exert the brake torque, but exerts the brake torque after a slight time lag. For this reason, the stage according to the comparative example is configured to operate the electromagnetic brake 58 so that the drive period of the drive motor 47 and the drive period of the electromagnetic brake 58 overlap with each other, and then stop driving the drive motor 47 at time tb2.

For the above reasons, in the method of operating the stage according to the comparative example, it takes time to switch between the drive motor 47 and the electromagnetic brake 58. Further, in the control of switching the on/off of the drive motor 47 and the electromagnetic brake 58, the motor power of the drive motor 47 and the brake power of the electromagnetic brake 58 also increase. For example, when operating the electromagnetic brake 58, it is necessary to supply 11 W as a rated power to the electromagnetic brake 58. Further, in the control of switching the on/off of the drive motor 47 and the electromagnetic brake 58, the load applied to the stage at the switching timing is likely to cause the base 35 to sink, and the stopping accuracy is deteriorated.

In contrast, the stage 30 according to this embodiment performs the coordinated control of the drive motor 47 and the electromagnetic brake 58. In this case, the stage controller 70 turns on the servo amplifier 81 of the driver part 80, and outputs the motor power from the driver part 80 to the drive motor 47. However, in order to perform the coordinated control, the motor controller 71 changes the motor current at an appropriate timing. Further, upon receiving a command from the motor controller 71, the brake controller 72 outputs the brake power from the driver part 80 to the electromagnetic brake 58 in order to eliminate a delay in the operation of the electromagnetic brake 58.

For example, in an initial stage of overdrive (times ta0 to ta1 in FIG. 7A), the motor controller 71 supplies a constant motor current to the drive motor 47 to raise the Z-axis movable body 46 of the lifter 45. The brake controller 72 supplies a high brake voltage once at time ta0 to make the electromagnetic brake 58 ready to exert its brake torque. Then, at time ta0′, some time after time ta0, the brake controller 72 lowers the brake voltage to a low voltage value to put the electromagnetic brake 58 on standby. As a result, after time ta0′, the electromagnetic brake 58 is in a state in which a weak brake torque is generated. This weak brake torque is a value at which the brake armature 582 is slightly in contact with the brake stator 581 (or is close enough not to contact with the brake stator 581), and has almost no influence on the rotation of the shaft portion 470 of the drive motor 47. Therefore, the lifter 45 may stably raise the Z-axis movable body 46 by the rotational drive of the drive motor 47.

When reaching time ta1, the stage controller 70 performs an operation of positioning the height position of the wafer W in the overdrive. This positioning is performed over the period from time ta1 to time ta2, and the raising of the wafer W (that is, the overdrive) ends at time ta2.

In the positioning, the stage controller 70 gradually reduces the motor power supplied to the drive motor 47 under the control of the motor controller 71. Meanwhile, the stage controller 70 gradually increases the brake power (brake voltage) supplied to the electromagnetic brake 58 under the control of the brake controller 72. This reduces the motor torque and increases the brake torque while keeping the holding force applied to the base 35 by both the drive motor 47 and the electromagnetic brake 58 (the entire lifter 45) substantially constant. Accordingly, the lifter 45 may apply a sufficient holding force against the load received from each probe 22 in the positioning.

When reaching time ta2, the motor power supplied to the drive motor 47 becomes zero, while the brake power supplied to the electromagnetic brake 58 becomes highest. However, as described above, the brake power of the electromagnetic brake 58 is quite small compared to the motor power for the drive motor 47 to maintain the height positions of the wafer W and the base 35. For example, the motor power for the drive motor 47 to maintain the height positions of the wafer W and the base 35 is set to about 35 W in the related art. In contrast, the brake power for one electromagnetic brake 58 to maintain the height positions of the wafer W and the base 35 is 0.5 W (see also FIG. 6B). Accordingly, the stage 30 may satisfactorily maintain the height positions of the wafer W and the base 35 with low power consumption.

Further, when correcting the height positions of the wafer W and the base 35, the stage controller 70 may adjust the height positions by controlling the drive motor 47 and the electromagnetic brake 58 in a coordinate manner. For example, FIG. 7A shows an operation of performing the correction after time ta3.

In this correction operation, the stage controller 70 gradually reduces the brake power (brake voltage) supplied to the electromagnetic brake 58 under the control of the brake controller 72. On the other hand, the stage controller 70 gradually increases the motor power (motor current) supplied to the drive motor 47 under the control of the motor controller 71.

Then, when reaching time ta4, the stage controller 70 maintains the brake power supplied to the electromagnetic brake 58 at a constant value, and also maintains the motor power supplied to the drive motor 47 at a constant value. Thus, the height positions of the wafer W and base 35 are corrected during the period from time ta4 to time ta5. The motor power (motor current) of the drive motor 47 is a value for applying a motor torque required to adjust the height position, and does not need to be a constant value. Further, the brake torque of the electromagnetic brake 58 at this time may be equal to or higher than the brake torque during the period from time ta0′ to time ta1.

At time ta5, the stage controller 70 gradually reduces the motor power supplied to the drive motor 47 under the control of the motor controller 71. Meanwhile, the stage controller 70 gradually increases the brake power (brake voltage) supplied to the electromagnetic brake 58 under the control of the brake controller 72. Thus, the electromagnetic brake 58 applies the brake torque to the shaft portion so that the stage 30 may firmly maintain the height positions of the wafer W and the base 35 with low power consumption.

The stage 30, the inspection device 1, and the method of operating the stage 30 are not limited to the above-described embodiment, and may be modified in various ways. For example, in the above-described embodiment, the Z-axis moving mechanism 40 is configured to raise the wafer W and the base 35 by the four lifters 45, but the number of lifters 45 is not limited. As an example, the Z-axis moving mechanism 40 may be configured to include three lifters 45, five or more lifters 45, or conversely, may be configured to include one lifter 45.

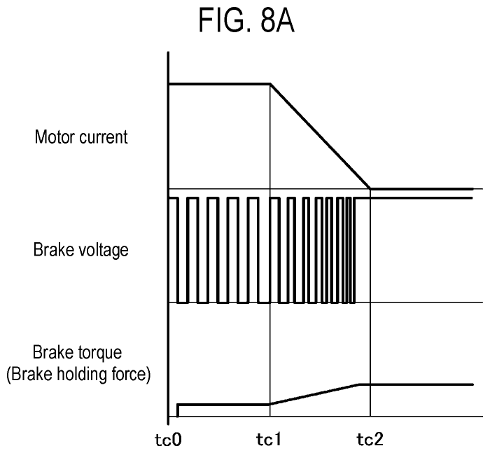

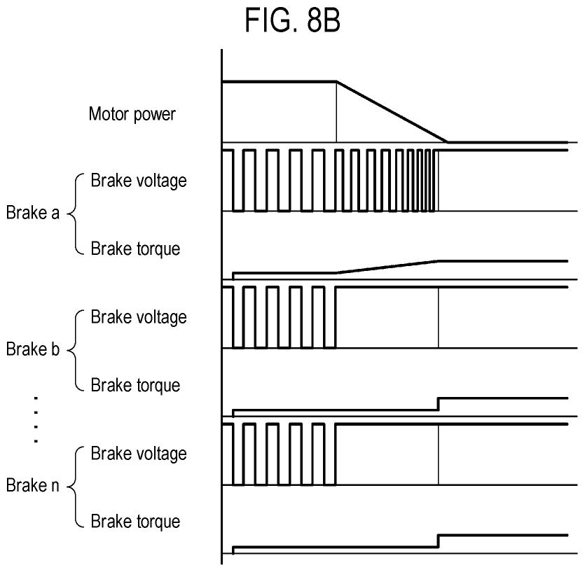

Further, the stage controller 70 may execute the PWM-control for the voltage control of the electromagnetic brake 58. Hereinafter, the method of operating the stage 30 when the PWM-control is performed will be described with reference to FIGS. 8A and 8B. FIG. 8A is a timing chart showing a relationship between the motor torque and the brake torque when the PWM-control is performed. FIG. 8B is a timing chart showing an example in which the PWM-control is performed on the stage 30 equipped with n lifters 45.

As shown in FIG. 8A, the stage 30 outputs a pulse wave brake voltage set to a constant value to the electromagnetic brake 58. For example, in the initial stage of overdrive (time tc0 to time tc1), the voltage controller 82 (see FIG. 5) outputs a brake voltage with a long pulse wave interval (off period). As a result, the electromagnetic brake 58 enters a state in which a weak brake torque that has almost no effect on the rotation of the shaft portion 470 of the drive motor 47 is generated. At this time, the motor controller 71 supplies a constant motor power (motor current) to the drive motor 47, causing the drive motor 47 to raise the wafer W and the base 35.

Then, at time tc1, the voltage controller 82 outputs a brake voltage with a shorter pulse wave interval (off period) than in the initial stage of overdrive. The voltage controller 82 also gradually narrows the pulse wave interval between time tc1 and time tc2. This enables the electromagnetic brake 58 to gradually increase the brake torque. At this time, the motor controller 71 also supplies a gradually decreasing motor power (motor current) to the drive motor 47, so that the motor torque of the drive motor 47 gradually decreases.

After time tc2, the height positions of the wafer W and the base 35 are maintained. At this time, the voltage controller 82 outputs a brake voltage with an even shorter pulse wave interval (or a pulse wave interval of zero). This enables the electromagnetic brake 58 to apply a strong brake torque to the shaft portion 470, which makes it possible to easily maintain the height positions of the wafer W and the base 35.

As described above, the stage 30 may precisely control the brake torque of the electromagnetic brake 58 by PWM-controlling the brake voltage supplied to the electromagnetic brake 58.

Further, as shown in FIG. 8B, the stage 30 may adjust the pulse wave interval of the brake voltage independently in the PWM-control of each lifter 45. Thus, the electromagnetic brake 58 of each lifter 45 may individually apply an appropriate brake torque according to the load on the wafer W and the base 35 and the inclination of the base 35, which makes it possible to stably control the posture of the wafer W.

The technical ideas and effects of the above-described embodiment of the present disclosure will be described below.

A first aspect of the present disclosure relates to the stage 30 including: the substrate support (base 35) configured to support a substrate (the wafer W); one or more lifters 45 configured to raise and lower the substrate support; and a controller (the stage controller 70) configured to control operations of the one or more lifters 45. Each of the one or more lifters 45 includes the drive motor 47 configured to output the thrust force to raise and lower the substrate support based on rotation, and the electromagnetic brake 58 configured to apply the brake holding force to the lifters 45 to maintain the height position of the substrate support. The controller controls the height position of the substrate support while mutually linking the thrust force of the drive motor 47 and the brake holding force of the electromagnetic brake 58.

According to the above configuration, the stage 30 may suppress power consumption during the movement of the stage 30 while stably receiving the load applied to the stage 30. That is, the stage 30 may incorporate the electromagnetic brake 58 into the control system of the drive motor 47 by controlling the thrust force of the drive motor 47 and the brake holding force of the electromagnetic brake 58 in a coordinated manner. Since the brake power of the electromagnetic brake 58 is sufficiently lower than the motor power of the drive motor 47, it is possible to significantly reduce the power consumption. Further, the deterioration of contact accuracy that occurs when switching between the electromagnetic brake 58 and the drive motor 47 may be eliminated by the coordinated control.

Further, the controller (the stage controller 70) adjusts the thrust force of the drive motor 47 and the brake holding force of the electromagnetic brake 58 so that the holding force for holding the substrate support (the base 35) at the height position of the substrate support is constant. Thus, the stage 30 may satisfactorily maintain the holding force of the substrate support.

Further, when the substrate support (the base 35) is held by the electromagnetic brake 58, the controller (the stage controller 70) gradually reduces the thrust force of the drive motor 47 while gradually increasing the brake holding force of the electromagnetic brake 58. Thus, the stage 30 may smoothly switch from the positioning by the drive motor 47 to the holding by the electromagnetic brake 58.

Further, the controller (the stage controller 70) allocates the thrust force of the drive motor 47 and the brake holding force of the electromagnetic brake 58 based on the target position of the substrate support (the base 35). Thus, the controller may appropriately set the thrust force and the brake holding force according to the height position.

Further, the controller (the stage controller 70) feeds back the actual position from the drive motor 47, calculates the deviation between the target position and the actual position, and allocates the thrust force of the drive motor 47 and the brake holding force of the electromagnetic brake 58 based on the deviation. By utilizing this deviation, the stage 30 may perform a process such as reducing the brake holding force of the electromagnetic brake 58, and may appropriately and efficiently perform an operation of coinciding the actual position of the substrate support (base 35) with the target position.

Further, the controller (the stage controller 70) sets the brake holding force of the electromagnetic brake 58 based on the motor power of the drive motor 47, and controls the brake power supplied to the electromagnetic brake 58 based on the set brake holding force. Thus, the stage 30 may satisfactorily control the brake holding force of the electromagnetic brake 58.

Further, the controller (the stage controller 70) controls the brake voltage to control the brake power supplied to the electromagnetic brake 58. Since the electromagnetic brake 58 may be treated as a linear resistance and the brake torque and brake power of the electromagnetic brake 58 are linear, it is possible to control the holding force by controlling the brake voltage of the electromagnetic brake. This makes it possible to perform the open loop control.

Further, the brake holding force of the electromagnetic brake 58 is adjusted by receiving the brake voltage that is PWM-controlled by the controller (the stage controller 70). Thus, the controller may control the electromagnetic brake 58 in a more ease manner.

Further, the controller (the stage controller 70) controls the operation of raising and positioning the substrate support (the base 35). Before the positioning operation, the controller supplies power to the electromagnetic brake 58 to provide the brake holding force capable of raising and lowering the lifters 45. Thus, the stage 30 may eliminate a dead time of the brake armature 582 that occurs due to mechanical characteristics by slip control.

Further, the controller (the stage controller 70) controls the operation of correcting the vertical position of the substrate support (the base 35). In the correcting operation, the controller increases the thrust force while decreasing the brake holding force, and then keeps the brake holding force constant to adjust the position of the substrate support by the thrust force. Thus, the stage 30 may move the lifters 45 smoothly and accurately even when the height position of the base 35 is corrected due to disturbances or the like.

A second aspect of the present disclosure relates to the inspection device 1 for bringing the probes 22 into contact with the substrate to inspect electrical characteristics of the substrate. The inspection device 1 includes: the stage 30 configured to hold and transfer the substrate (the wafer W). The stage 30 includes a substrate support (the base 35) configured to support the substrate, one or more lifters 45 configured to raise and lower the substrate support, and a controller (the stage controller 70) configured to control operations of the one or more lifters 45. Each of the one or more lifters 45 includes the drive motor 47 configured to output the thrust force to raise and lower the substrate support based on rotation, and the electromagnetic brake 58 configured to apply the brake holding force to the one or more lifters 45 to maintain the height position of the substrate support. The controller controls the height position of the substrate support while mutually linking the thrust force of the drive motor 47 and the brake holding force of the electromagnetic brake 58.

A third aspect of the present disclosure relates to the method of operating the stage 30. The stage 30 includes a substrate support (the base 35) configured to support a substrate (the wafer W), and one or more lifters 45 configured to raise and lower the substrate support. Each of the one or more lifters 45 includes the drive motor 47 configured to output the thrust force to raise and lower the substrate support based on rotation, and the electromagnetic brake 58 configured to apply the brake holding force to the lifters 45 to maintain the height position of the substrate support. The method includes: controlling the height position of the substrate support while mutually linking the thrust force of the drive motor 47 and the brake holding force of the electromagnetic brake 58. In the second and third aspects described above, the power consumption during the movement of the stage 30 may be suppressed while stably receiving the load applied to the stage 30.

According to the present disclosure in some embodiments, it is possible to suppress power consumption during movement of a stage while stably receiving load applied to the stage.

The stage 30, the inspection device 1, and the method of operating the stage 30 according to the embodiments disclosed herein are exemplary and not limitative in all respects. The embodiments may be modified and improved in various forms without departing from the spirit and scope of the appended claims. The matters described in the aforementioned embodiments may have other configurations to the extent that they are not contradictory, and may be combined to the extent that they are not contradictory.

What is claimed is:

1. A stage comprising:
a substrate support configured to support a substrate;
one or more lifters configured to raise and lower the substrate support; and
a controller configured to control operations of the one or more lifters,
wherein each of the one or more lifters includes a drive motor configured to output a thrust force to raise and lower the substrate support based on rotation, and an electromagnetic brake configured to apply a brake holding force to the one or more lifters to maintain a height position of the substrate support, and
wherein the controller controls the height position of the substrate support while mutually linking the thrust force of the drive motor and the brake holding force of the electromagnetic brake.

2. The stage of claim 1, wherein the controller adjusts the thrust force of the drive motor and the brake holding force of the electromagnetic brake so that the holding force for holding the substrate support at the height position of the substrate support is constant.

3. The stage of claim 2, wherein when the substrate support is held by the electromagnetic brake, the controller gradually reduces the thrust force of the drive motor while gradually increasing the brake holding force of the electromagnetic brake.

4. The stage of claim 2, wherein the controller allocates the thrust force of the drive motor and the brake holding force of the electromagnetic brake based on a target position of the substrate support.

5. The stage of claim 4, wherein the controller feeds back an actual position from the drive motor, calculates a deviation between the target position and the actual position, and allocates the thrust force of the drive motor and the brake holding force of the electromagnetic brake based on the deviation.

6. The stage of claim 4, wherein the controller sets the brake holding force of the electromagnetic brake based on motor power of the drive motor, and controls brake power supplied to the electromagnetic brake based on the set brake holding force.

7. The stage of claim 6, wherein the controller controls a brake voltage to control the brake power supplied to the electromagnetic brake.

8. The stage of claim 7, wherein the brake holding force of the electromagnetic brake is adjusted by receiving a brake voltage that is PWM-controlled by the controller.

9. The stage of claim 1, wherein the controller controls an operation of raising and positioning the substrate support, and
wherein, before the positioning, power is supplied to the electromagnetic brake to provide the brake holding force capable of raising and lowering the one or more lifters.

10. The stage of claim 1, wherein the controller controls an operation of correcting a vertical position of the substrate support, and
wherein, in the correcting, the controller increases the thrust force while decreasing the brake holding force, and keeps the brake holding force constant to adjust the position of the substrate support by the thrust force.

11. An inspection device for bringing probes into contact with a substrate to inspect electrical characteristics of the substrate, comprising:
a stage configured to transfer the substrate placed thereon,
wherein the stage includes:
a substrate support configured to support the substrate;
one or more lifters configured to raise and lower the substrate support; and
a controller configured to control operations of the one or more lifters, wherein each of the one or more lifters includes:
a drive motor configured to output a thrust force to raise and lower the substrate support based on rotation; and
an electromagnetic brake configured to apply a brake holding force to the one or more lifters to maintain a height position of the substrate support, and wherein the controller controls the height position of the substrate support while mutually linking the thrust force of the drive motor and the brake holding force of the electromagnetic brake.

12. A method of operating a stage including a substrate support configured to support a substrate, and one or more lifters configured to raise and lower the substrate support,
wherein each of the one or more lifters includes a drive motor configured to output a thrust force to raise and lower the substrate support based on rotation, and an electromagnetic brake configured to apply a brake holding force to the one or more lifters to maintain a height position of the substrate support,
the method including:
controlling the height position of the substrate support while mutually linking the thrust force of the drive motor and the brake holding force of the electromagnetic brake.
